(19) United States
(12) Patent Application Publication
(10) Pub. No.: US 2008/0274584 A1
(43) Pub. Date: Nov. 6, 2008

(54) Method of microwave annealing for enhancing organic electronic devices

(75) Inventors: Fang-Chung Chen, Jhushan Township (TW); Chu-Jung Ko, Taipei City (TW); Yi-Kai Lin, Hualien County (TW)

Correspondence Address: REED SMITH LLP, 3110 FAIRVIEW PARK DRIVE, SUITE 1400, FALLS CHURCH, VA, 22042, US

(73) Assignee: National Chiao Tung University

(21) Appl. No.: 11/822,823

(22) Filed: Jul. 10, 2007

(30) Foreign Application Priority Data
May 4, 2007 (TW) 096116004

(51) Int. Cl. H01L 51/40

(52) U.S. Cl. 438/99; 257/E51.002

(57) ABSTRACT

A method of microwave annealing for enhancing the properties of organic electronic devices is provided, including the steps of providing organic electronic devices and then microwave annealing the organic electronic devices. Because microwave annealing is non-contact and requires only a short time for annealing, and also because it anneals a target selectively and may anneal only the organic active layer of organic electronic device, microwave annealing allows organic molecules in the organic active layer to be rearranged quickly, so as to improve the arrangement of the organic molecules, and this in turn elevates the quantum efficiency thereof and enhances the properties of the organic electronic devices.

### FIELD OF THE INVENTION

The invention relates to a method of microwave annealing for enhancing the properties of organic electronic devices, and more particularly to a method of microwave annealing for enhancing performance of organic photovoltaic devices.

### DESCRIPTION OF PRIOR ART

Generally, organic electronic devices consist of several thin films and may be deposited at low temperature, thus the organic electronic devices may be applied to a variety of substrates and manufactured in the form of large surface area. In addition, the low cost and simple fabrication process of the organic electronic devices means that they will be applied to a wide range of electronic products in the future. An organic electronic devices basically comprises two electrodes and an organic active layer disposed therebetween, and various organic electronic devices are currently available, such as organic solar cells, organic light emitting diodes (OLED), and organic thin film transistors (OTFT).

In an organic solar cell, electricity is generated after the cell absorbs light and then activates the electrons and holes in the organic active layer of the organic solar cell. In an organic light emitting diode, the two electrodes respectively inject electrons and holes into the organic active layer and convert the resulted energy into visible light. In an organic thin film transistor, the transistor starts to function when it first reacts to a voltage applied to the gate therein, and then the electrons or holes generated in the organic active layer are transmitted between the source and the drain therein.

The key to the application of the organic electronic devices is the enhancement of the properties of the organic electronic devices. Taking the organic solar cell as an example, the quantum efficiency of an organic solar cell without annealing is approximately 1%, but it has been known that annealing may further refine the arrangement of the organic molecules in the organic active layer, which increases the quantum efficiency of the organic solar cell. The method of annealing may be divided into two types; one is thermal annealing and the other is solvent annealing.

A method of thermal annealing was disclosed on page 1617 in vol. 15 of Advanced Functional Materials in 2005, with the title of “Thermally Stable, Efficient Polymer Solar Cells with Nanoscale Control of the Interpenetrating Network Morphology”. A heating oven or hot plate is used to heat a substrate of an organic solar cell via heat conduction, and then the substrate will pass the heat energy to the organic active layer, thereby annealing the polymers in the organic active layer and thus enhancing the alignment of the polymers, which enhances the properties of the organic solar cell and elevates the quantum efficiency thereof. However, thermal annealing via the heating oven or hot plate cannot selectively target a desired part of the organic electronic device for annealing, and the annealing process thereof not only is time-consuming but also wastes excessive energy on parts of the organic electronic device that do not require annealing.

A method of solvent annealing was disclosed on page 864 in vol. 4 of Natural Materials in November of 2005, with the title of “High-efficiency Solution Processable Polymer Photovoltaic Cells by Self-organization of Polymer Blends”. Polymers in the organic materials were rearranged by lowering the rate of solvent evaporation, so as to increase the quantum efficiency of the polymer photovoltaic cells. However, the process of such solvent annealing required approximately 20 minutes to complete, which is excessively time-consuming and this in turn renders the method less cost-effective for actual production.

### SUMMARY OF THE INVENTION

In order to solve the problems existing in the conventional thermal annealing and solvent annealing, including a waste of energy, time-consuming, and spending excessive energy on parts of the organic electronic device that do not require annealing, a method of microwave annealing is disclosed in the invention, which selectively targets the organic active layer of organic electronic devices for annealing. Moreover, the method completes the process of annealing rapidly, consequently elevating the extent of arrangement of the organic molecules in the organic active layer, thereby enhancing the properties of the organic electronic devices.

To achieve the aforesaid aims, a method of microwave annealing for enhancing the properties of organic electronic devices is disclosed in the invention, comprising: providing an organic electronic device, and then microwave annealing the organic electronic device; wherein the microwave annealing is carried out via a microwave generator.

The aforesaid organic electronic device may be an organic solar cell, an organic light detector, an organic light emitting diode, or an organic thin film transistor.

The aforesaid organic electronic device comprises a substrate having an organic active layer disposed thereon.

The aforesaid substrate may be a glass substrate or a plastic substrate.

The aforesaid microwave annealing process is carried out after an organic active layer is formed in the organic electronic device.

The aforesaid microwave generator generates an operational bandwidth of microwave ranging between 300 MHz and 300 GHz.

The aforesaid microwave generator generates an operational bandwidth of microwave ranging between 13.55 MHz and 13.57 MHz.

The aforesaid microwave generator generates an operational bandwidth of microwave ranging between 902 MHz and 928 MHz.

The aforesaid microwave generator generates an operational bandwidth of microwave ranging between 2.4 MHz and 2.5 MHz.

The aforesaid microwave generator generates an operational bandwidth of microwave ranging between 5.725 GHz and 5.875 GHz.

The aforesaid microwave generator generates an operational bandwidth of microwave ranging between 24.025 GHz and 24.275 GHz.

The aforesaid microwave generator generates a microwave power ranging between 300 watts and 1200 watts.

The aforesaid microwave generator generates a microwave power ranging between 500 watts and 700 watts.

The aforesaid microwave annealing takes more than 20 seconds in duration.

The aforesaid microwave annealing takes between 85 seconds and 95 seconds in duration.

The implementation of the invention brings about following advantages:

1. Selectively heats an organic electronic device and anneals an organic active layer thereof directly, effectively reduces the waste of energy during annealing.

2. Effectively shortens the time required for annealing, which speeds up the process of annealing and elevates the productivity in actual production of organic electronic devices.

In order to allow anyone of ordinary skill in the art to better understand the technical content of the invention and carry out implementation thereof, a preferred embodiment of the invention is provided to illustrate the details and advantages of the invention, so that the purposes and advantages of the invention are easily comprehended according to the disclosed contents, claims, and drawings thereof.

### BRIEF DESCRIPTION OF DRAWINGS

The structure and the technical means adopted by the present invention to achieve the above and other objectives can be best understood by referring to the following detailed description of the preferred embodiments and the accompanying diagrams, wherein:

FIG. 1 is a flow chart that shows a method of microwave annealing for enhancing the properties of organic electronic devices according to the invention.

FIG. 2A is a schematic view that shows an organic electronic device according to the invention.

FIG. 2B is a schematic view that shows an embodiment of the method of microwave annealing according to the invention.

FIG. 3 is a diagram that shows the relationship between the temperature of the organic active layer and the annealing time resulted from different methods of annealing according to the embodiment of the invention.

FIG. 4 is a diagram that shows the results of X-ray diffraction to the organic active layer annealed via different methods of annealing according to the embodiment of the invention.

FIG. 5 is a diagram that shows the properties of current density-voltage under different microwave annealing time for the organic solar cell according to the embodiment of the invention.

FIG. 6A is a diagram that shows the relationship between the open-circuit voltage and annealing time for the organic solar cell according to the embodiment of the invention.

FIG. 6B is a diagram that shows the relationship between the short-circuit current density and annealing time for the organic solar cell according to the embodiment of the invention.

FIG. 6C is a diagram that shows the relationship between the filling factor and annealing time for the organic solar cell according to the embodiment of the invention.

FIG. 6D is a diagram that shows the relationship between the quantum efficiency and annealing time for the organic solar cell according to the embodiment of the invention.

### DETAILED DESCRIPTION OF PREFERRED EMBODIMENTS

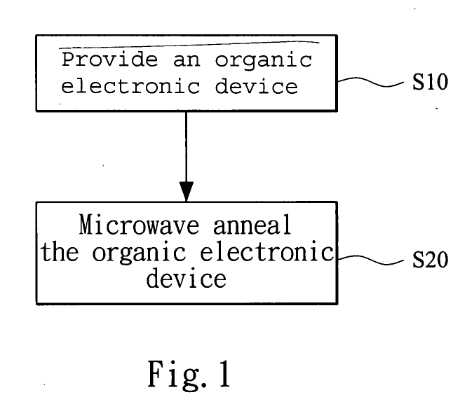

As shown in FIG. 1, a method of microwave annealing for enhancing the properties of an organic electronic device 20 is disclosed, comprising: providing an organic electronic device S10; and microwave annealing the organic electronic device S20.

Provide an organic electronic device S10; the organic electronic device 20 may be an organic solar cell, an organic light detector, an organic light emitting diode, or an organic thin film transistor.

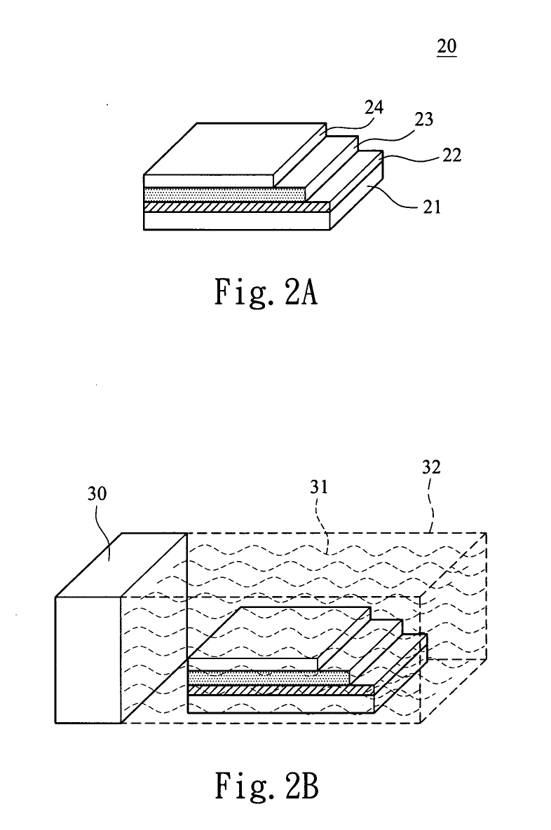

As shown in FIG. 2A, the organic electronic device 20 comprises a substrate 21 having a first conductive layer 22 formed thereon, the organic electronic device 20 is fabricated from forming an organic active layer 23 on the substrate 21, and then forming a second conductive layer 24 on the organic active layer 23, so that the organic electronic device 20 is formed as a sandwich structure in which the order of layers is “the first conductive layer 22—the organic active layer 23—the second conductive layer 24” from the bottom up.

The substrate 21 may be a glass substrate or a plastic substrate. The material of the plastic substrate may be polyethylene teraphthalate (PET) or polycarbonate. The organic electronic device 20 made from plastic substrates has advantages such as flexibility, light in weight, low cost, and may be manufactured in the form of large surface area at low temperature. The first conductive layer 22 may be selected from the group consisting of transparent conductors and semi-transparent conductors, whereas the second conductive layer 24 may also be selected from the group consisting of a transparent conductor and a semi-transparent conductor. The transparent conductor is selected from the group consisting of indium tin oxide (ITO) and indium zinc oxide (IZO), while the semi-transparent conductor may be a thin metal layer, and the metal of the thin metal layer is selected from the group consisting of silver, aluminum, titanium, nickel, copper, gold, and chromium.

Referring to FIG. 2B, microwave annealing the organic electronic device S20 is resulted from exposing the organic electronic device 20 to a microwave 31 generated from a microwave generator 30 in a microwave field 32; the microwave field 32 may be in an open space or a microwave chamber. After organic molecules in the organic active layer 23 has absorbed energy from the microwave 31 and begun to vibrate, the organic molecules are rearranged into a more refined arrangement during the vibration, which in turn enhances the arrangement of the organic molecules. Because the organic molecules are more compactly arranged, the speed of transmitting electrons and holes in the organic active layer 23 is increased, and thus quantum efficiency of the organic active layer 23 is elevated, thereby enhancing the properties of the organic electronic device 20.

In the embodiment of the invention, the organic electronic device 20 that has been through the packaging process may be placed in the microwave field 32 in order to undergo microwave annealing; or the step of microwave annealing may be carried out after the organic active layer 23 has been formed on the substrate 21. The organic electronic device 20 may undergo further processes after microwave annealing has been completed.

The operational bandwidth of the microwave 31 generated from the microwave generator 30 may range between 13.55 MHz and 13.57 MHz, 300 MHz and 300 GHz, 902 MHz and 928 MHz, 2.4 MHz and 2.5 MHz, 5.725 GHz and 5.875 GHz, or 24.025 GHz and 24.275 GHz. The preferable operational bandwidth for the microwave 31 is 13.56 MHz, 915 MHz, 2.45 GHz, 5.8 GHz, or 24.15 GHz. The microwave power for the microwave 31 ranges between 300 watts and 1200 watts, and the preferable microwave power for the microwave 31 is between 500 watts and 700 watts.

During the process of microwave annealing, the microwave 31 may target the organic active layer 23 only, and thus other parts of the organic electronic device 20 will not be affected by the microwave annealing; further, the energy of the microwave 31 is concentrated on the organic active layer 23, which not only saves energy but also allows the annealing process to be completed quickly. The time required for microwave annealing is generally 20 seconds or more, and the preferable time for microwave annealing is between 85 seconds and 95 seconds. In addition, because the microwave annealing process is non-contact and may target only the organic active layer 23, it may be combined with the batch-type fabrication process in order to speed up the annealing process and subsequently increase productivity in actual production, while also enhancing the properties of the organic electronic device 20 at the same time.

To facilitate better understanding toward the effects of the invention, an embodiment of the invention is provided for this purpose, in which an organic solar cell having an organic active layer 23 made of Poly(3-hexylthiophene)/1-(3-methoxycarbonyl)-propyl-1phenyl-(6,6) C₆₁ (P3HT/PCBM) is used as an example.

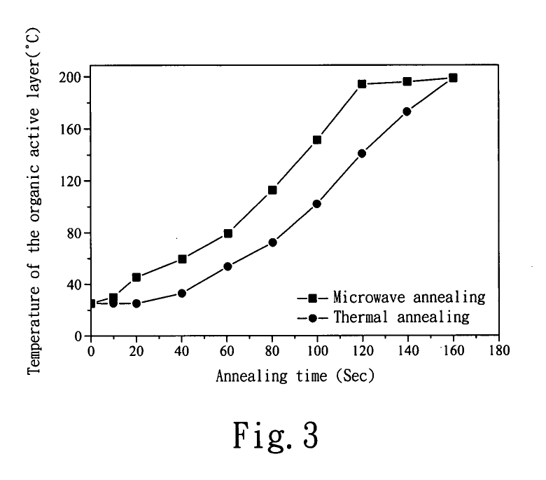

Referring to FIG. 3, the organic solar cell was respectively annealed via thermal annealing by using a 200° C. hot plate, and annealed via microwave annealing by using a microwave 31 with a power of 600 watts and an operational bandwidth of 2.45 GHz.

To carry out thermal annealing by using the hot plate, the substrate 21 needs to be heated beforehand, so that the heat is passed on from the substrate 21 to the organic active layer 23 via heat conduction, which subsequently anneals the organic molecules in the organic active layer 23, and required a longer time to complete the annealing process. With respect to microwave annealing, the organic molecules in the organic active layer 23 are vibrated via the energy of the microwave 31, so that the organic molecules are rearranged and this consequently further refines the arrangement of the organic molecules; because the energy of the microwave 31 is directly focused on the organic active layer 23, the time for annealing may be significantly reduced. Therefore, in the circumstance of obtaining the same temperature in the organic active layer, the method of microwave annealing achieves the goal faster than that of the method of thermal annealing. In other words, the method of microwave annealing of the invention achieves the effect of annealing more quickly.

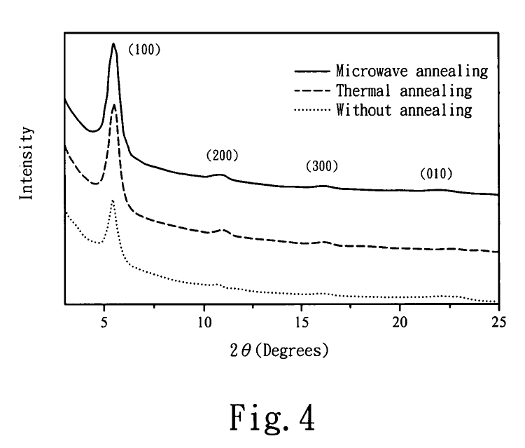

FIG. 4 shows the results of X-ray diffraction to the organic active layer annealed via different methods of annealing; the process of X-ray diffraction was carried out by using an X-ray diffractometer of the model X′Pert Pro from PANalytical, and the organic active layer is made of P3HT/PCBM that was either unannealed, annealed via thermal annealing for 30 minutes, or annealed via microwave annealing for 90 seconds. It should be noted that when the two-fold incident angle (2θ) of the X-ray diffraction is 5.4 degrees and the lattice orientation is [100], microwave annealing for 90 seconds showed the strongest intensity of diffraction, which indicates that the arrangement of organic molecules in the organic active layer 23 resulted from microwave annealing was the most refined. In other words, the arrangement of organic molecules in the organic active layer 23 may be enhanced most quickly by using the method of microwave annealing of the invention.

When the load resistance of the organic solar cell is infinitely large, which means the external current is cut off (with a current value of zero), and the resulted voltage is called the open-circuit voltage (V_{OC}); on the other hand, when the voltage is zero, the resulted current density is called the short-circuit current density (J_{SC}). Moreover, in the curve that shows the current density-voltage property of the organic solar cell, the output power (P) of any operating point is resulted from multiplying the voltage (V) by the current density (J); wherein a operating point (Vₘ, Jₘ) has a maximum output power (Pₘ, Pₘ=Vₘ×Jₘ). The division of the maximum output power by the product of the open-circuit voltage and the short-circuit current density results in the filling factor (FF, FF=(Vₘ×Jₘ)/(V_{OC}×J_{SC})).

A preferable organic solar cell has to have not only high open-circuit voltage and short-circuit current density, but also a value of the filling factor which is close to 1. This is because the filling factor indicates how close the maximum output power is to the product of the open-circuit voltage and short-circuit current density. Furthermore, the quantum efficiency (η, η=(V_{OC}×J_{SC}×FF)/Pᵢₙ) of the organic solar cell is defined as the ratio between the outputted energy and the inputted light energy (Pᵢₙ), which means the closer the value of the filling factor is to 1, the higher the quantum efficiency of the organic solar cell.

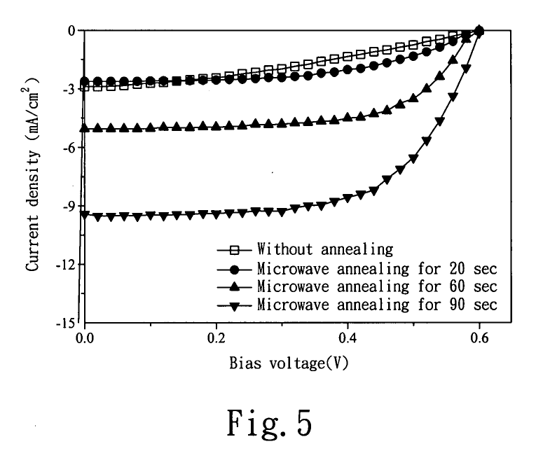

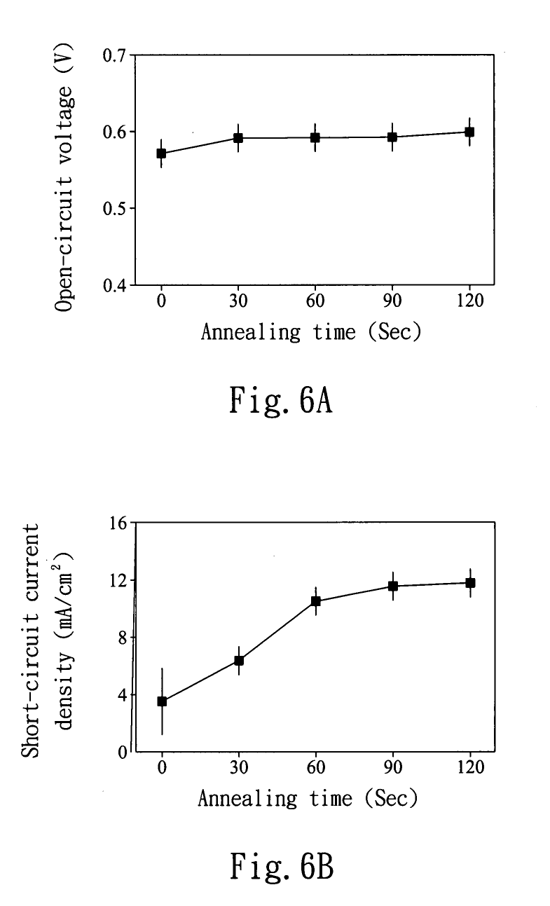

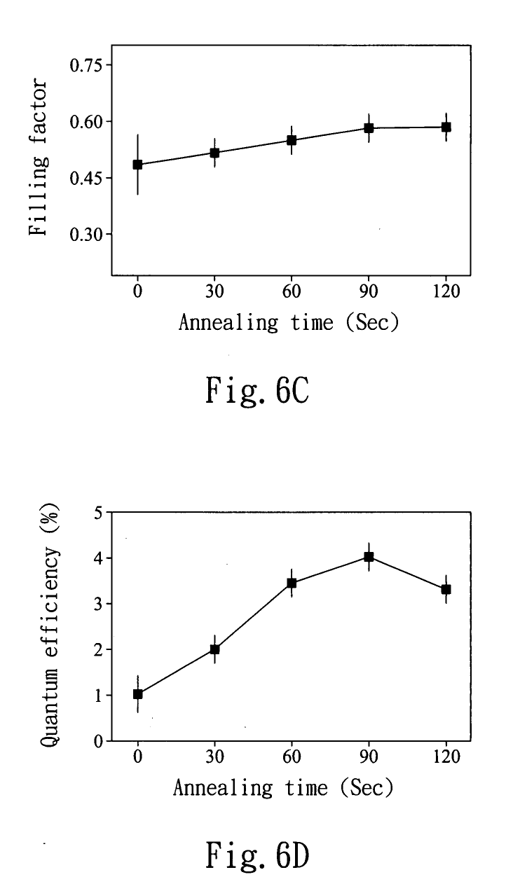

Referring to FIGS. 5 and 6A, it should be noted that the open-circuit voltage of the organic solar cell did not decrease relatively as the time of microwave annealing was increased. This indicates that the microwave annealing did not damage the first conductive layer 22 and the second conductive layer 24; hence the open-circuit voltage of the organic solar cell is maintained.

Referring to FIGS. 6B, 6C, and 6D, which show that the short-circuit current density and the filling factor of the organic solar cell increased along with the increment in the time of microwave annealing. This indicated that microwave annealing also enhances the properties of the organic solar cell, whereas the quantum efficiency of the organic solar cell also increased relatively; the preferable time of microwave annealing is between 85 seconds and 95 seconds, and the most preferable time of microwave annealing is 90 seconds. When the time of microwave annealing is 90 seconds, the quantum efficiency of the organic solar cell increased from 1% to 4.1%.

By implementing the method of microwave annealing according to the invention, the properties of the organic solar cell are effectively enhanced in a short period of time. Therefore, when the method of the invention is applied to other organic electronic device 20, the properties of the organic electronic device 20 are also quickly enhanced.

Although a preferred embodiment of the invention has been described for purposes of illustration, it is understood that various changes and modifications to the described embodiment can be carried out without departing from the scope and the spirit of the invention as disclosed in the appended claims.

What is claimed is:

1. A method of microwave annealing for enhancing properties of organic electronic devices, comprising:
providing an organic electronic device; and
microwave annealing the organic electronic device, in which the microwave annealing is carried out via a microwave generator.

2. The method of claim 1, wherein the organic electronic device is an organic solar cell, an organic light detector, an organic light emitting diode, or an organic thin film transistor.

3. The method of claim 1, wherein the organic electronic device comprises a substrate having an organic active layer disposed thereon.

4. The method of claim 3, wherein the substrate is a glass substrate or a plastic substrate.

5. The method of claim 1, wherein the microwave annealing is carried out after an organic active layer is formed in the organic electronic device.

6. The method of claim 1, wherein the microwave generator generates an operational bandwidth of microwave ranging between 300 MHz and 300 GHz.

7. The method of claim 1, wherein the microwave generator generates an operational bandwidth of microwave ranging between 13.55 MHz and 13.57 MHz.

8. The method of claim 1, wherein the microwave generator generates an operational bandwidth of microwave ranging between 902 MHz and 928 MHz.

9. The method of claim 1, wherein the microwave generator generates an operational bandwidth of microwave ranging between 2.4 MHz and 2.5 MHz.

10. The method of claim 1, wherein the microwave generator generates an operational bandwidth of microwave ranging between 5.725 GHz and 5.875 GHz.

11. The method of claim 1, wherein the microwave generator generates an operational bandwidth of microwave ranging between 24.025 GHz and 24.275 GHz.

12. The method of claim 1, wherein the microwave generator generates a microwave power ranging between 300 watts and 1200 watts.

13. The method of claim 1, wherein the microwave generator generates a microwave power ranging between 500 watts and 700 watts.

14. The method of claim 1, wherein the microwave annealing takes more than 20 seconds.

15. The method of claim 1, wherein the microwave annealing takes between 85 seconds and 95 seconds.
